(19) United States
(12) Patent Application Publication
(10) Pub. No.: US 2014/0183034 A1
(43) Pub. Date: Jul. 3, 2014

(54) ANTIMAGNETIC SPUTTERING DEVICE AND METHOD FOR DRIVING THE SAME

(71) Applicants: Hyun Soo NOH, Yongin-City (KR); Kyeong Sik YOON, Yongin-City (KR)

(72) Inventors: Hyun Soo NOH, Yongin-City (KR); Kyeong Sik YOON, Yongin-City (KR)

(21) Appl. No.: 13/937,286

(22) Filed: Jul. 9, 2013

(30) Foreign Application Priority Data
Dec. 27, 2012 (KR) 10-2012-0155193

(51) Int. Cl. C23C 14/35

(52) U.S. Cl. CPC C23C 14/35
USPC 204/192.12; 204/298.15

(57) ABSTRACT

An antimagnetic sputtering device and a method for driving the same, the device including a vacuum chamber; a chuck on a bottom side of an inside of the vacuum chamber, the chuck providing a space on which a substrate is to be seated; a target on an upper side of the inside of the vacuum chamber, the target facing the chuck; a magnet on an upper portion of the target; a driving unit that drives the magnet; and a control unit that controls the driving unit to move the magnet at predetermined time intervals while the device is in a standby mode after completion of a sputtering process for the substrate.

### CROSS-REFERENCE TO RELATED APPLICATIONS

This application is based on and claims priority from Korean Patent Application No. 10-2012-0155193, filed on Dec. 27, 2012 in the Korean Intellectual Property Office, the disclosure of which is incorporated herein in its entirety by reference.

### BACKGROUND

1. Field

Embodiments relates to an antimagnetic sputtering device and a method for driving the same.

2. Description of the Prior Art

Sputtering is a process of depositing a thin film on a substrate, which applies impact to a surface of a target (that is made of a material for forming the thin film) by particles having energy. Thus, the material secedes and discharges from the surface of the target through momentum exchange at the time of the impact. Since this process is not a chemical or thermal reaction process, but rather is a mechanical process using the momentum, it has the advantage that any material can be used as the material of the target, and thus it has been widely used as a thin film forming process.

### SUMMARY

After the sputtering process for the substrate is completed, the magnet is positioned on one side in a standby mode. However, if the magnet stays in one position for a long time, the target that is positioned adjacent to the magnet may be magnetized. In this case, the deposition uniformity of the target particles, which are deposited on the substrate in the subsequently performed sputtering process, may deteriorate.

One subject to be solved by the present invention is to provide an antimagnetic sputtering device and a method for driving the same, which can prevent the occurrence of magnetization in a certain position of a target in a standby mode of a sputtering process for a substrate, and thus can prevent deterioration of deposition uniformity of target particles that are deposited on the substrate in the subsequently performed sputtering process.

Additional advantages, subjects, and features of the invention will be set forth in part in the description which follows and in part will become apparent to those having ordinary skill in the art upon examination of the following or may be learned from practice of the invention.

According to an aspect of the present invention, there is provided an antimagnetic sputtering device comprising: a vacuum chamber; a chuck arranged on a bottom side of an inside of the vacuum chamber and providing a space on which a substrate is seated; a target arranged on an upper side of the inside of the vacuum chamber to face the chuck; a magnet arranged on an upper portion of the target; a driving unit driving the magnet; and a control unit controlling the driving unit to move the magnet at predetermined time intervals in a standby mode after completion of a sputtering process for the substrate.

According to another aspect of the present invention, there is provided a method for driving an antimagnetic sputtering device comprising: a standby mode signal receiving step of receiving a standby mode signal from a process control unit to a control unit when a sputtering process for a substrate that is arrange on a lower portion of a target is completed; and a magnet movement control step of determining that the present mode is a standby mode if the control unit receives the standby mode signal, and moving the magnet at predetermined time intervals by controlling a driving unit that drives the magnet, which is arranged on an upper portion of the target, repeats movement between a home position that corresponds to one side of the target and an end position that corresponds to the other side of the target during the sputtering process, and is positioned in the home position when the sputtering process is completed.

According to the embodiments of the present invention, at least the following effects can be achieved.

According to the antimagnetic sputtering device and the method for driving the same according to the embodiments of the present invention, since the magnet is moved at predetermined time intervals in a standby mode after a sputtering process for a substrate is completed, the magnet is prevented from staying in a home position for a long time in the standby mode, and thus the target is prevented from being magnetized by the magnet.

Accordingly, the antimagnetic sputtering device according to the embodiment of the present invention can improve the deposition uniformity of the target particles that are deposited on the substrate in the subsequent sputtering process that is performed after the standby mode.

The effects according to the present invention are not limited to the contents as exemplified above, but further various effects are included in the description.

### BRIEF DESCRIPTION OF THE DRAWINGS

The embodiments will be apparent from the following detailed description taken in conjunction with the accompanying drawings, in which:

FIG. 1 illustrates a cross-sectional view of an antimagnetic sputtering device according to an embodiment;

FIG. 2 illustrates a cross-sectional view of a case where a magnet illustrated in FIG. 1 is arranged inside a vacuum chamber;

FIG. 3 illustrates a view explaining an operation of a magnet during standby mode after completion of a sputtering process with respect to a substrate illustrated in FIG. 1;

FIG. 4 illustrates a view explaining another operation of a magnet during standby mode after completion of a sputtering process with respect to a substrate illustrated in FIG. 1;

FIG. 5 illustrates a flowchart of a method for driving an antimagnetic sputtering device according to an embodiment;

FIG. 6 illustrates a flowchart illustrating in detail a step S20 illustrated in FIG. 5; and

FIG. 7 illustrates a flowchart illustrating another example of step S20 in FIG. 5.

### DETAILED DESCRIPTION

Advantages and features of the embodiments and methods of accomplishing the same may be understood more readily by reference to the following detailed description of preferred embodiments and the accompanying drawings. The embodiments may, however, be embodied in many different forms and should not be construed as being limited to the embodiments set forth herein. Rather, these embodiments are provided so that this disclosure will be thorough and complete and will fully convey the concept of the embodiments to those skilled in the art, and the present invention will only be defined by the appended claims.

It will also be understood that when a layer is referred to as being “on” another layer or substrate, it can be directly on the other layer or substrate, or intervening layers may also be present. The same reference numbers indicate the same components throughout the specification.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Hereinafter, preferred embodiments of the present invention will be described with reference to the accompanying drawings.

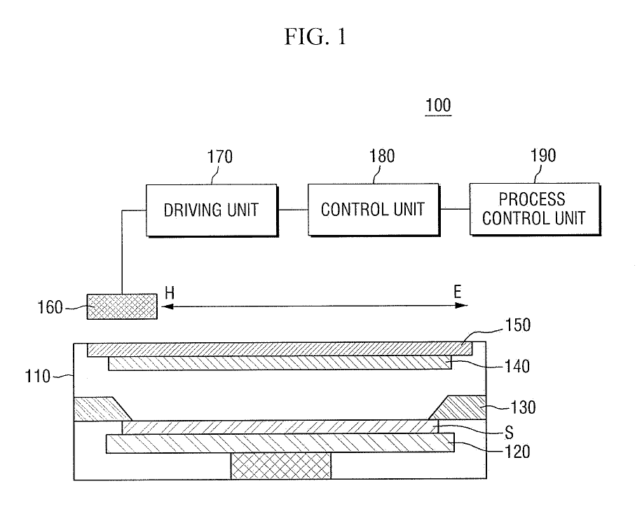

FIG. 1 illustrates a cross-sectional view of an antimagnetic sputtering device according to an embodiment.

Referring to FIG. 1, an antimagnetic sputtering device 100 may include a process or vacuum chamber 110, a chuck 120, a mask 130, a target 140, a back plate 150, a magnet 160, a driving unit 170, a control unit 180, and a process control unit 190. This antimagnetic sputtering device 100 is a device that performs a sputtering process that is a method for depositing a thin film on a substrate S.

The process or vacuum chamber 110 provides an inner space in which vacuum may be formed. In an implementation, although not illustrated, a gas supply tube for supplying an inert gas, e.g., argon gas, to the inside of the vacuum chamber 110 may be installed on one side of the process or vacuum chamber 110, and a gas discharge tube for exhausting a process gas that remains in the process or vacuum chamber 110 after the process is installed on the other side of the process or vacuum chamber 110.

The chuck 120 may be on a bottom side of an inside of the vacuum chamber 110, and may provide a space on which the substrate S is to be seated. The substrate S may be a substrate for a display. For example, the substrate S may be a substrate for a flat display, such as an organic light emitting display, a liquid crystal display, or a PDP device. The substrate S may be a bare substrate or a substrate on which a structure, e.g., a thin film or wiring, is formed.

The mask 130 may be on an upper portion of the substrate S, and may be used to form a thin film in a desired position of the substrate S.

The target 140 may be on an upper side of the inside of the vacuum chamber 110 and may face the chuck 120. The target 140 may be formed of a material of the thin film to be formed on the substrate S. The target 140 may correspond to a source that forms the thin film on the substrate S by producing target particles by a magnetic field. The target 140, may be made of, e.g., a metal material, such as aluminum, an aluminum alloy, refractory metal silicide, gold, copper, titanium, titanium-tungsten, tungsten, or molybdenum, or an inorganic material, such as silicon dioxide.

The back plate 150 may be between an upper portion of the vacuum chamber 110 and the target 140 and may support the target 140. The back plate 150 may supply DC power provided from a power supply to the target 140. If the DC power is applied to the target 140, plasma may be generated between the target 140 and the substrate S, and thus the inert gas may be activated.

The magnet 160 may be outside the vacuum chamber 110 in a position that corresponds to an upper portion of the target 140. The magnet 160 may apply a magnetic field to the target 140, and may include a permanent magnet. The magnet 160 may apply the magnetic field to the target 140 to generate the target particles from the target 140. The target particles may be deposited on the substrate S along the magnetic field formed by the magnet 160 that moves when the inert gas (which is activated by the plasma generated between the target 140 and the substrate S) collides with the target 140 to sputter the target 140.

The movement of the magnet 160 may be repeatedly performed between a home (H) position (that corresponds to one side of the target 140) and an end (E) position (that corresponds to another side of the target 140) in the sputtering process for the substrate S. If the sputtering process for the substrate S is completed, and a present mode or period becomes a standby mode or period (i.e., if the device is in standby mode), the magnet 160 may be positioned in the home (H) position. Although not illustrated, in an implementation, the movement of the magnet 160 may be performed along a guide rail connected to a ball screw.

Further, the movement of the magnet 160 may also be performed at predetermined time intervals in or during the standby mode or period after the sputtering process for the substrate S is completed. This will be described in detail below.

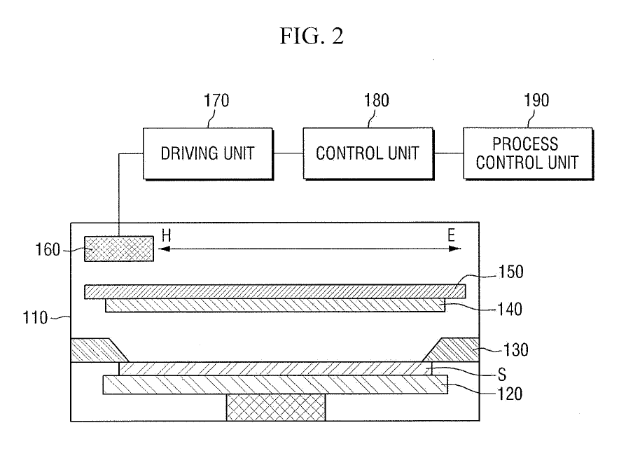

FIG. 1 illustrates that the magnet 160 is arranged outside the vacuum chamber 110. However, the magnet 160 may be arranged inside the vacuum chamber 110 as shown in FIG. 2.

The driving unit 170 may drive the magnet 160, and may include, e.g., a motor. By the operation of such a motor, the magnet 160 may move along the guide rail.

The control unit 180 may control the driving unit 150. For example, the control unit 180 may direct movement of the magnet 160 at predetermined time intervals in or during the standby mode or period after the completion of the sputtering process for the substrate S. Accordingly, if the magnet 160 stays in the home (H) position for a long time after completion of the sputtering process for the substrate S, the control unit 180 may help reduce the likelihood and/or prevent the target 40 (that is positioned adjacent to the magnet 160) from being magnetized. Thus, the control unit 180 may help reduce and/or prevent the undesirable deterioration of deposition uniformity of the target particles that are deposited on the substrate S in a subsequent sputtering process due to magnetization of any one portion of the target 140 in or during the standby mode of the sputtering process for the substrate S. The predetermined time may be a time when the deposition uniformity of the target particles deposited on the substrate S becomes lower than a reference value due to the magnet 160 staying in the home (H) position during the standby mode or period. The predetermined time may be predetermined through experiments, and may differ depending on, e.g., a magnetization strength of the magnet 160.

The process control unit 190 may control the sputtering process for the substrate S that is performed in the vacuum chamber 110. Further, during the standby mode or period (after the completion of the sputtering process for the substrate S), the process control unit 190 may transmit a standby mode signal to the control unit 180 so that the control unit 180 operates in standby mode.

Next, an operation of the control unit 180 (which controls the movement of the magnet 160 to help prevent the target 140 from being magnetized by the magnet 160 while in standby mode after the completion of the sputtering process for the substrate S) will be described in detail.

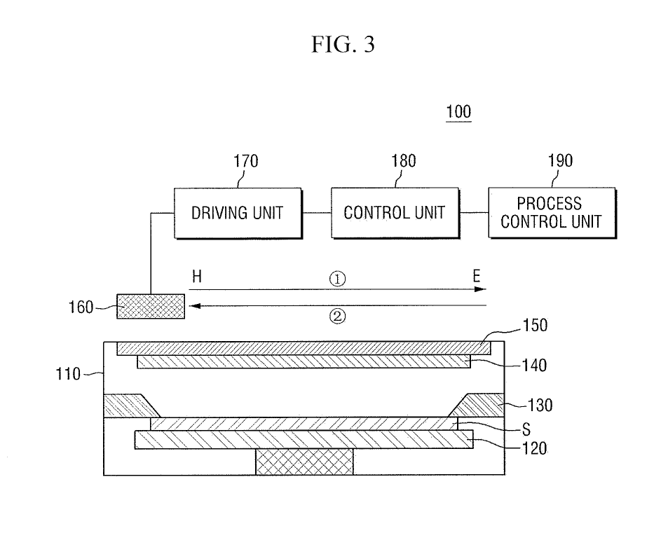

FIG. 3 illustrates a view explaining the operation of a magnet while the device is in a standby mode after completion of a sputtering process with respect to a substrate illustrated in FIG. 1.

Referring to FIG. 3, if a first predetermined time has elapsed while the device is in standby mode, the control unit 180 may control the driving unit 170 to move the magnet 160 from the home (H) position to the end (E) position (\textcircled{1}). Then, if a second predetermined time has elapsed after the first predetermined time, and the device is still in standby mode, the control unit 180 may control the driving unit 170 to move the magnet 160 from the end (E) position to the home (H) position (\textcircled{2}). The first predetermined time may be equal to the second predetermined time.

As described above, the control unit 180 may help prevent the magnet 160 from staying only in the home (H) position for a long time while the device is in standby mode, and thus may help prevent the magnet 160 from undesirably magnetizing the target 140.

Next, another operation of the control unit 180 (which controls the movement of the magnet 160 to prevent the target 140 from being magnetized by the magnet 160 while the device is in the standby mode after the completion of the sputtering process for the substrate S) will be described in detail.

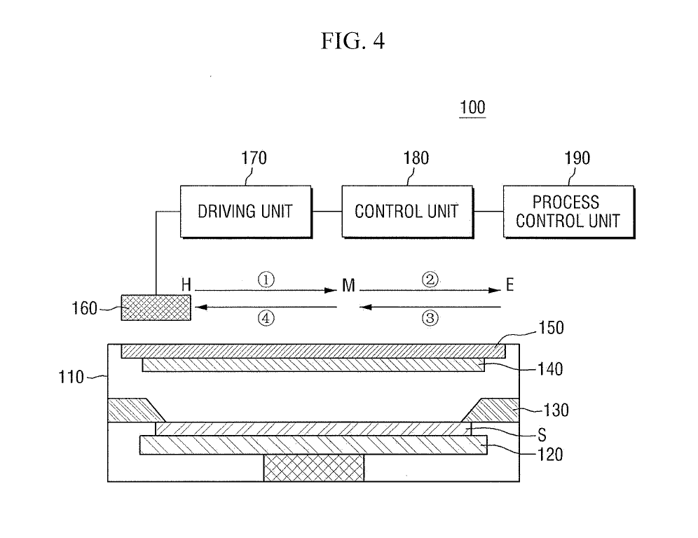

FIG. 4 illustrates a view explaining another operation of a magnet while the device is in a standby mode after completion of a sputtering process with respect to a substrate illustrated in FIG. 1.

Referring to FIG. 4, if a first predetermined time has elapsed while the device is in standby mode, the control unit 180 may control the driving unit 170 to move the magnet 160 from the home (H) position to a middle (M) position (that is between the home (H) position and the end (E) position (\textcircled{1})). Then, if a second predetermined time has elapsed after the first predetermined time and the device is still in standby mode, the control unit 180 may control the driving unit 170 to move the magnet 160 from the middle (M) position to the end (E) position (\textcircled{2}). Then, if a third predetermined time has elapsed after the second predetermined time and the device is still in standby mode, the control unit 180 may control the driving unit 170 to move the magnet 160 from the end (E) position to the middle (M) position (\textcircled{3}). Then, if a fourth predetermined time has elapsed after the third predetermined time and the device is still in standby mode, the control unit 180 may control the driving unit 170 to move the magnet 160 from the middle (M) position to the home (H) position (\textcircled{4}). In an implementation, the first predetermined time, the second predetermined time, the third predetermined time, and the fourth predetermined time may be equal to one another.

As described above, the control unit 180 may sub-divide the movement of the position of the magnet 160 by setting the middle (M) position between the home (H) position and the end (E) position. The control of the control unit 180 to move the magnet 160 to sub-divided positions (while the device is in standby mode) as described above may be efficient in the case where a standby time is long, e.g., if the device is in standby mode for an extended period.

As described above, in the antimagnetic sputtering device 100 according to an embodiment, by moving the magnet 160 at the predetermined time intervals while the device is in standby mode (after the completion of the sputtering process for the substrate S), the magnet 160 may be prevented from staying in the home (H) position for a long time after completion of the sputtering process for the substrate S, and thus the magnet 160 may be prevented from undesirably magnetizing the target 140.

Accordingly, the antimagnetic sputtering device 100 according to an embodiment may help improve deposition uniformity of the target particles that are deposited on the substrate S in a subsequent sputtering process for the substrate S that is performed after the device has been in standby mode.

Next, a method for driving an antimagnetic sputtering device 100 according to an embodiment will be described with reference to FIGS. 1 and 5-7.

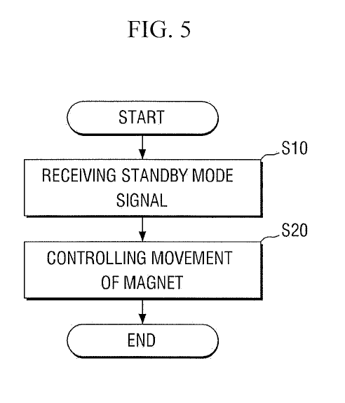

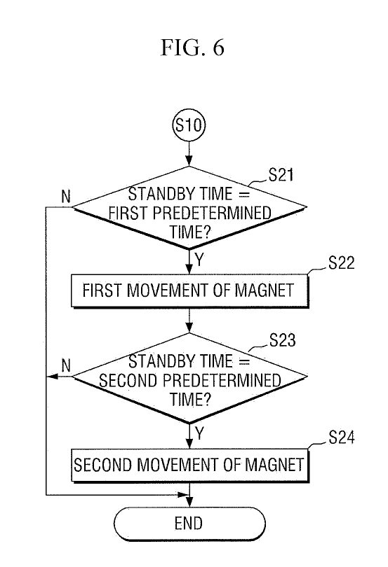

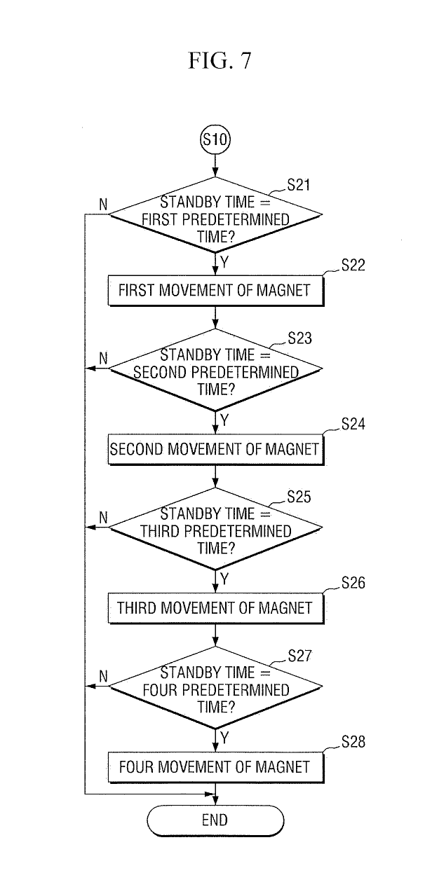

FIG. 5 illustrates a flowchart of a method for driving an antimagnetic sputtering device according to an embodiment. FIG. 6 illustrates a flowchart that shows details of a step S20 illustrated in FIG. 5, and FIG. 7 illustrates a flowchart showing another example of a step S20 in FIG. 5.

Referring to FIG. 5, the method for driving an antimagnetic sputtering device according to an embodiment may include a standby mode signal receiving step S10 and a magnet movement control step S20.

The standby mode signal receiving step S10 may include receiving a standby mode signal from the process control unit 190 by the control unit 180 when the sputtering process (for the substrate S that is arrange on a lower portion of the target 140) is completed.

The magnet movement control step S20 may include determining that a present mode of the device is standby mode if the control unit 180 receives the standby mode signal. The magnet movement control step S20 may further include moving the magnet 160 at predetermined time intervals by controlling the driving unit 170 that drives the magnet 160, which is arranged on an upper portion of the target 140. For example, the driving unit 170 may repeatedly move the magnet 160 between the home (H) position (that corresponds to one side of the target 140) and the end (E) position (that corresponds to the other side of the target 140) during the sputtering process and when the device is in standby mode. In an implementation, the magnet 160 may be positioned in the home (H) position when the sputtering process is completed. In an implementation, if a subsequent sputtering process is ready to be performed, the standby mode or period may be ended, and the magnet 160 may be returned to the home (H) position.

Referring to FIG. 6, in the magnet movement control step S20, the control unit 180 may determine whether a first predetermined time has elapsed while the device is in standby mode of the sputtering process (S21). If it is determined that the first predetermined time has elapsed and the device is still in standby mode, the control unit 180 may control the driving unit 170 to first move the magnet 160 from the home (H) position to the end (E) position (S22). Then, the control unit 180 may determine whether a second predetermined time has elapsed after the first predetermined time while the device is still in standby mode of the sputtering process (S23). If it is determined that the second predetermined time has elapsed and the device is still in standby mode, the control unit 180 may control the driving unit 170 to then move the magnet 160 from the end (E) position to the home (H) position (S24).

In an implementation, referring to FIG. 7, in the magnet movement control step S20, the control unit 180 may determine whether a first predetermined time has elapsed while the device is in standby mode of the sputtering process (S21). If it is determined that the first predetermined time has elapsed and the device is still in standby mode, the control unit 180 may control the driving unit 170 to first move the magnet 160 from the home (H) position to the middle (M) position (that is between the home (H) position and the end (E) position (S22)). Then, the control unit 180 may determine whether a second predetermined time has elapsed after the first predetermined time while the device is still in standby mode of the sputtering process (S23). If it is determined that the second predetermined time has elapsed and the device is still in standby mode, the control unit 180 may control the driving unit 170 to then move the magnet 160 from the middle (M) position to the end (E) position (S24). Then, the control unit 180 may determine whether a third predetermined time has elapsed after the second predetermined time while the device is still in standby mode of the sputtering process (S25). If it is determined that the third predetermined time has elapsed and the device is still in standby mode, the control unit 180 may control the driving unit 170 to then move the magnet 160 from the end (E) position to the middle (M) position (S26). Then, the control unit 180 may determine whether a fourth predetermined time has elapsed after the third predetermined time while the device is still in standby mode of the sputtering process (S27). If it is determined that the fourth predetermined time has elapsed and the device is still in standby mode, the control unit 180 may control the driving unit 170 to then move the magnet 160 from the middle (M) position to the home (H) position (S28).

By way of summation and review, a thin-film forming method by sputtering may include a diode sputtering method, a bias sputtering method, a high-frequency sputtering method, a triode sputtering method, and a magnetron sputtering method. Among them, the most frequently used one is the magnetron sputtering method.

The magnetron sputtering method is a sputtering method in which target particles (which are generated from a target when inert gas that is activated by plasma generated between a substrate and the target, to which a DC power is applied, collides with the target to sputter the target) are deposited on the substrate along a magnetic field that is formed by a moving magnet mounted on the rear surface of the target.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. An antimagnetic sputtering device, comprising:
a vacuum chamber;
a chuck on a bottom side of an inside of the vacuum chamber, the chuck providing a space on which a substrate is to be seated;
a target on an upper side of the inside of the vacuum chamber, the target facing the chuck;
a magnet on an upper portion of the target;
a driving unit that drives the magnet; and
a control unit that controls the driving unit to move the magnet at predetermined time intervals while the device is in a standby mode after completion of a sputtering process for the substrate.

2. The antimagnetic sputtering device of claim 1, further comprising a process control unit that transmits a signal for the standby mode to the control unit.

3. The antimagnetic sputtering device of claim 1, wherein the magnet:
repeatedly moves between a home position that corresponds to one side of the target and an end position that corresponds to another side of the target during the sputtering process, and
is positioned in the home position when the sputtering process is completed.

4. The antimagnetic sputtering device of claim 3, wherein the control unit controls the driving unit to move the magnet from the home position to the end position if a first predetermined time has elapsed and the device is still in standby mode.

5. The antimagnetic sputtering device of claim 4, wherein the control unit controls the driving unit to move the magnet from the end position to the home position if a second predetermined time has elapsed after the first predetermined time has elapsed and the device is still in standby mode.

6. The antimagnetic sputtering device of claim 3, wherein the control unit controls the driving unit to move the magnet from the home position to a middle position that is between the home position and the end position if a first predetermined time has elapsed and the device is still in standby mode.

7. The antimagnetic sputtering device of claim 6, wherein the control unit controls the driving unit to move the magnet from the middle position to the end position if a second predetermined time has elapsed after the first predetermined time has elapsed and the device is still in standby mode.

8. The antimagnetic sputtering device of claim 7, wherein the control unit controls the driving unit to move the magnet from the end position to the middle position if a third predetermined time has elapsed after the second predetermined time has elapsed and the device is still in standby mode.

9. The antimagnetic sputtering device of claim 8, wherein the control unit controls the driving unit to move the magnet from the middle position to the home position if a fourth predetermined time has elapsed after the third predetermined time has elapsed and the device is still in standby mode.

10. The antimagnetic sputtering device of claim 1, wherein the magnet is positioned outside the vacuum chamber.

11. The antimagnetic sputtering device of claim 1, wherein the magnet is positioned inside the vacuum chamber.

12. The antimagnetic sputtering device of claim 1, wherein the driving unit is a motor, and the magnet moves by an operation of the motor.

13. The antimagnetic sputtering device of claim 1, further comprising a back plate between the target and the magnet, the back plate supporting the target.

14. A method for driving an antimagnetic sputtering device, the method comprising:
a standby mode signal receiving step including receiving a standby mode signal from a process control unit by a control unit when a sputtering process for a substrate that is arrange on a lower portion of a target is completed; and
a magnet movement control step including:
determining that a present mode is a standby mode if the control unit receives the standby mode signal, and
moving the magnet at predetermined time intervals by controlling a driving unit that drives the magnet, which is arranged on an upper portion of the target, by:
repeatedly moving the magnet between a home position that corresponds to one side of the target and an end position that corresponds to another side of the target during the sputtering process, and
positioning the magnet in the home position when the sputtering process is completed.

15. The method for driving an antimagnetic sputtering device of claim 14, wherein, in the magnet movement control step, the control unit controls the driving unit to move the magnet from the home position to the end position if a first predetermined time has elapsed and the device is still in standby mode.

16. The method for driving an antimagnetic sputtering device of claim 15, wherein in the magnet movement control step, the control unit controls the driving unit to move the magnet from the end position to the home position if a second predetermined time has elapsed after the first predetermined time has elapsed and the device is still in standby mode.

17. The method for driving an antimagnetic sputtering device of claim 14, wherein in magnet movement control step, the control unit controls the driving unit to move the magnet from the home position to a middle position that is between the home position and the end position if a first predetermined time has elapsed and the device is still in standby mode.

18. The method for driving an antimagnetic sputtering device of claim 17, wherein in the magnet movement control step, the control unit controls the driving unit to move the magnet from the middle position to the end position if a second predetermined time has elapsed after the first predetermined time has elapsed and the device is still in standby mode.

19. The method for driving an antimagnetic sputtering device of claim 18, wherein in the magnet movement control step, the control unit controls the driving unit to move the magnet from the end position to the middle position if a third predetermined time has elapsed after the second predetermined time has elapsed and the device is still in standby mode.

20. The method for driving an antimagnetic sputtering device of claim 19, wherein in the magnet movement control step, the control unit controls the driving unit to move the magnet from the middle position to the home position if a fourth predetermined time has elapsed after the third predetermined time has elapsed and the device is still in standby mode.
